(19) United States
(12) Patent Application Publication
(10) Pub. No.: US 2004/0216017 A1
(43) Pub. Date: Oct. 28, 2004

(54) Control circuit and method for testing memory control modle

(76) Inventor: Simon Chu, Taipei (TW)

Correspondence Address: MADSON & METCALF, GATEWAY TOWER WEST, SUITE 900, 15 WEST SOUTH TEMPLE, SALT LAKE CITY, UT, 84101

(21) Appl. No.: 10/827,464

(22) Filed: Apr. 19, 2004

(30) Foreign Application Priority Data
Apr. 22, 2003 (TW) 092109403

(51) Int. Cl. H04L 1/22; H04B 1/74; H02H 3/05; H05K 10/00; G11C 29/00; H03K 19/003

(52) U.S. Cl. 714/718

(57) ABSTRACT

A control circuit for testing a memory control module is provided. The memory control module includes first and second memory blocks. The control circuit includes a processing unit and a control chip. The processing unit executes a memory testing program specific to the first memory block, and asserts data read/write commands. The control chip is in communication with the processing unit and the memory control module, and accesses to the first and second memory blocks of the memory control module for test in response to the data read/write commands in first and second states, respectively. A mapping circuit and one or more selected address lines between the control chip and the memory control module are used to switch the states of the data read/write commands.

### FIELD OF THE INVENTION

The present invention relates to a control circuit, and particularly to a control circuit for testing a memory control module. The present invention also relates to a method for testing a memory control module.

### BACKGROUND OF THE INVENTION

With the increasing demand on the operating speed of a personal computer, a large memory size is required. For complying with the increasing memory size, the control chip of the personal computer needs more address pins in order to access the memory.

Generally, a memory testing tool stipulated in the art is employed to test control chips or memory control modules so that convincing testing results can be obtained. The memory testing tool is executed by a central processing unit of a personal computer. During the testing operation, the central processing unit can access any data in the addresses of the memory control module for test.

Referring to FIG. 1, a conventional memory testing scheme of a computer system is illustrated. In the figure, circuit blocks including a central processing unit 10, a north bridge chip 20, a memory control module 30, a south bridge chip 40 and a hard disc 50 are shown. The central processing unit 10 is connected to the north bridge chip 20 via a front side bus 12. The north bridge chip 20 is connected to the memory control module 30 via a memory bus 22, and the south bridge chip 40 is connected to another bus 24 in a specific format. The south bridge chip 40 is connected to the hard disc 50 where the memory testing tool is stored. For testing the memory control module 30, the memory testing tool stored in the hard disc 50 is executed by the central processing unit 10. In response to the memory testing tool, the central processing unit 10 asserts data read/write commands to the memory control module 30 to read/write data via the north bridge chip 20 so as to test the memory control module 30.

Conventionally, the memory testing tool is executed under a DOS operation system in a big real mode. In the big real mode, the central processing unit 10 can only address the memory control module 30 up to 4 gigabits (GB) via 32 address lines bit0˜bit31, as shown in FIG. 2. In other words, the address space beyond the 4-GB limit fails to be accessed and tested by this memory testing tool.

For a new-generation operation system such as Window 2000, the address space of the memory control module 30 is usually greater than 4 GB. Therefore, the test of the memory control module becomes difficult.

### SUMMARY OF THE INVENTION

The present invention provides a control circuit and a method capable of testing a memory control module having address space greater than 4 GB.

In accordance with a first aspect of the present invention, there is provided a control circuit for testing a memory control module. The memory control module comprises first and second memory blocks. The control circuit comprises a processing unit and a control chip. The processing unit executes a memory testing program specific to the first memory block, and asserts data read/write commands. The control chip is in communication with the processing unit and the memory control module, and accesses to the second memory block of the memory control module for test in response to the data read/write commands in a first state.

Preferably, the control chip further accesses to the first memory block of the memory control module for test in response to the data read/write commands in a second state.

In an embodiment, the control circuit comprises a mapping circuit for switching the data read/write commands between the first and second states and mapping the data read/write commands in the first state onto the second memory block of the memory control module.

In an embodiment, the processing unit and the control chip are a central processing unit and a north bridge chip of a computer system, respectively, the mapping circuit is included in the north bridge chip, and the first and second states are different logic states.

In an embodiment, the control chip changes the level of a specific address line between the control chip and the memory control module to different values so as to switch the read/write commands between the first and second states.

In an embodiment, the first memory block includes 2ⁿ addresses, the control circuit comprises n counts of address lines corresponding to the read/write commands and at least one specific address line between the control chip and the memory control module for indicating states of the read/write commands.

In an embodiment, the control circuit comprises one specific address line to indicate high-level and low-level states of the read/write commands as the first and second states.

Preferably, the second memory block has the same address space as the first memory block and designated with higher addresses than the first memory block. For example, the value n is equal to 32, and each of the first memory block and the second memory block has a 4-GB address space.

In another embodiment, the control circuit comprises m counts of specific address lines, where m is greater than one, to indicate 2^{m} counts of states of the read/write commands for testing third memory blocks of the memory control module in addition to the first and second memory blocks.

Preferably, the control circuit further comprises switch-setting means for determining when the first and second states are entered, respectively. For example, the switch-setting means is the BIOS of a computer system or a timer.

In accordance with a second aspect of the present invention, there is provided a control circuit for testing a memory control module of a computer system. The memory control module comprises at least first and second memory blocks. The control circuit comprises a central processing unit, a north bridge chip and a mapping circuit. The central processing unit asserts data read/write commands for testing the first memory block of the memory control module. The north bridge chip is in communication with the central processing unit and the memory control module, and has the first memory block of the memory control module respond to the data read/write commands to be tested at a first time point. The mapping circuit is in communication with the memory control module, and maps the data read/write commands onto the second memory block of the memory control module to have the second memory block respond to the data read/write commands to be tested at a second time point.

In an embodiment, the mapping circuit is incorporated into the north bridge chip.

In an embodiment, the control circuit further comprises at least one specific address line between the mapping circuit and the memory control module, which have different logic states at the first and second time points.

In accordance with a third aspect of the present invention, there is provided a control method for testing a memory control module. The memory control module has an address space greater than the testing limit of a memory testing tool. Firstly, the memory control module is divided into at least a first memory block and a second memory block, wherein each of the memory blocks has an address space within the testing limit of the memory testing tool. Then, the first memory block is responded to data read/write commands asserted in response to the memory testing tool in a first situation. Then, the second memory block is responded to the data read/write commands in a second situation.

In an embodiment, the first and second memory blocks are identical in address space and the second memory block is designed with higher addresses than the first memory block.

In an embodiment, the memory testing tool is specific to the test of the first memory block, and the method further comprises a step of mapping the data read/write commands onto the second memory block in the second situation.

In an embodiment, the testing limit of the memory testing tool is 4 GB, and the memory control module is divided into a plurality of memory blocks, each having a 4-GB address space.

In an embodiment, the first situation indicates a first logic state of the read/write commands, and the second situation indicates a second logic state of the read/write commands different from the first logic state.

In an embodiment, the first and second situations are switched in response to a timing result.

In an embodiment, the first and second situations are switched according to the settings in the BIOS.

When the memory control module is divided into more than two memory blocks, more than two different logic states are preferably sequentially imparted to the read/write commands to have the memory blocks respond to the read/write commands in turn.

In an embodiment, the first and second logic states of the read/write commands are determined by a mapping circuit incorporated in a north bridge chip and coupled to the memory control module.

In an embodiment, the memory testing tool is executed and the read/write commands are asserted by a central processing unit in a big real mode.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a circuit block diagram showing a conventional memory testing scheme of a computer system;

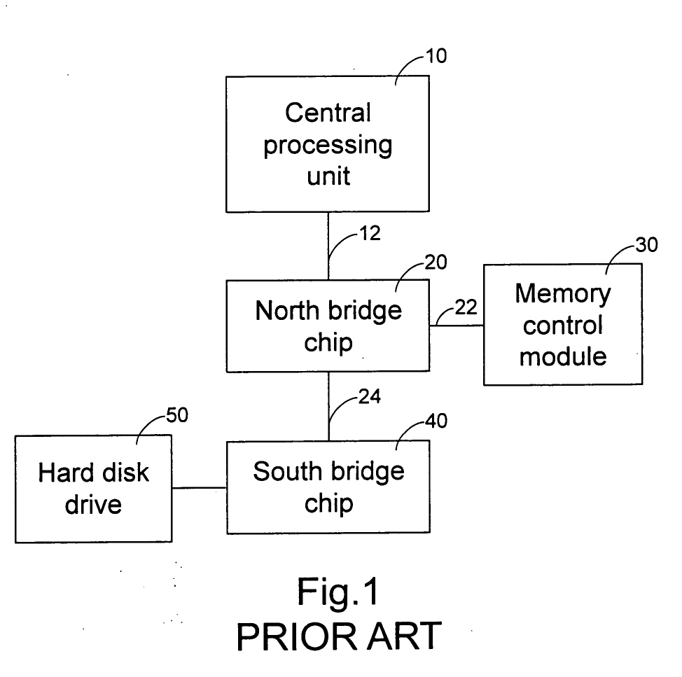

FIG. 2 schematically illustrates a 4-GB memory control module and corresponding address lines for a memory testing tool to be executed under a DOS operation system in a big real mode;

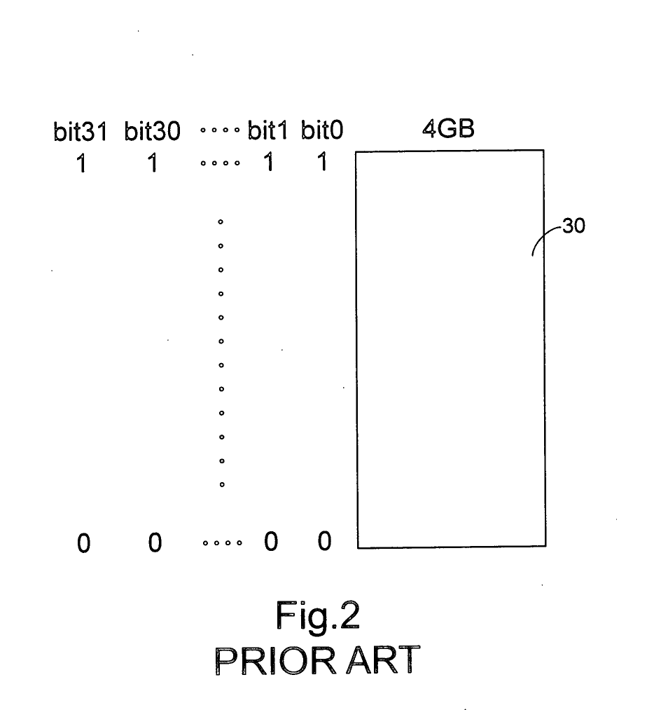

FIG. 3 is a circuit block diagram showing a memory testing scheme of a computer system according a first preferred embodiment of the present invention;

FIG. 4 schematically illustrates an 8-GB memory control module and corresponding address lines for a memory testing tool to be executed according to the present invention; and

FIG. 5 is a circuit block diagram showing a memory testing scheme of a computer system according a second preferred embodiment of the present invention.

### DETAILED DESCRIPTION OF THE PREFERRED EMBODIMENT

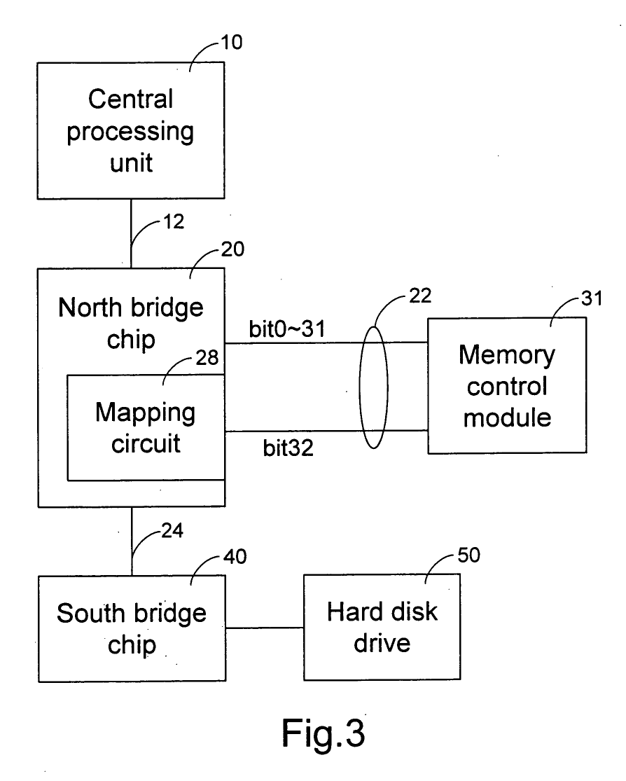

Referring to FIG. 3, a memory testing control circuit of a computer system according a preferred embodiment of the present invention is illustrated. As shown, a central processing unit 10, a north bridge chip 20 incorporating therein a mapping circuit 28, a memory control module 31, a south bridge chip 40 and a hard disc drive 50 of the computer system are shown. In this embodiment, the memory control module 31 has address space of 8 GB.

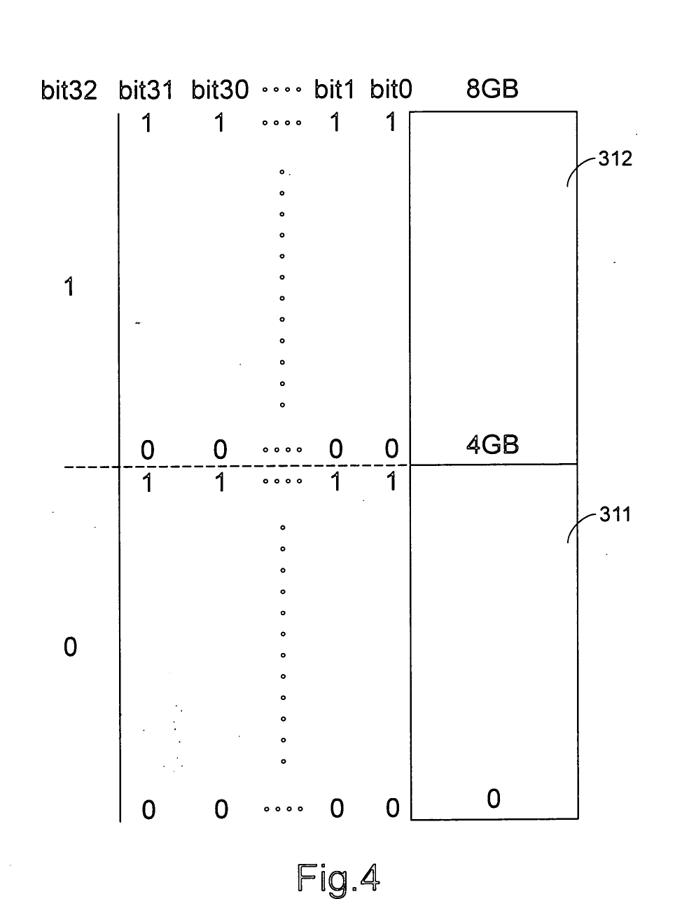

The central processing unit 10 is connected to the north bridge chip 20 via a front side bus 12. The north bridge chip 20 is connected to the memory control module 30 via a memory bus 22, and the south bridge chip 40 is connected to another bus 24 in a specific format. The south bridge chip 40 is connected to the hard disc 50 where the memory testing tool is stored. When the memory testing tool conventionally used for testing memory control module up to 4 GB is applied hereto for testing the memory control module 31, the memory control module 31 is divided into a first memory block 311 and a second memory block 312, each of which has address space of 4 GB, as shown in FIG. 4, and are addressed via 32 address lines bit0˜bit31. The mapping circuit 28 is incorporated in the north bridge chip 20 for converting addresses and data between the memory bus 22 and the front side bus 12, which can be achieved by controlling the logic state of the address line bit32 additionally arranged between the mapping circuit 28 of the north bridge chip 20 and the memory control module 31.

The method for testing the memory control module 31 will be described in more details hereinafter. Firstly, the memory testing tool stored in the hard disc 50 is executed by the central processing unit 10. The memory testing tool is specific to the first memory block 311 whose address space is designated as the former 4 GB. According to the memory testing tool, the central processing unit 10 asserts data read/write commands via address lines bit0˜bit32. The logic state of the last bit on the address line bit32 is referred to determine which of the first and second memory blocks 311 and 312 is tested. When the last bit is in a low-level state “0”, the data read/write commands are addressed to the first memory block 311 of the memory control module 31 to read/write data via the north bridge chip 20 so as to test the first memory block 311 of the memory control module 31 according to the memory testing tool. Subsequently, the memory testing tool stored in the hard disc 50 is executed again by the central processing unit 10 while the mapping circuit 28 switches the last bit on the address line bit32 into a high-level state “1”. Accordingly, the data read/write commands originally addressed to the first memory block 311 are mapped onto the second memory block 312 of the memory control module 31 by the mapping circuit 28 for testing the second memory block 312 of the memory control module 31. In other words, while the addressed space on the front-side bus 12 is still the first memory block 311, the addressed space on the memory bus 22 has become the second memory block 312. By this way, even if the same memory testing tool specific to the first memory block 311 is applied, the latter 4-GB address space of the memory control module 31 can be accessed and tested. Therefore, the memory control module 31 having address space higher than 4 GB can still be tested in a big real mode.

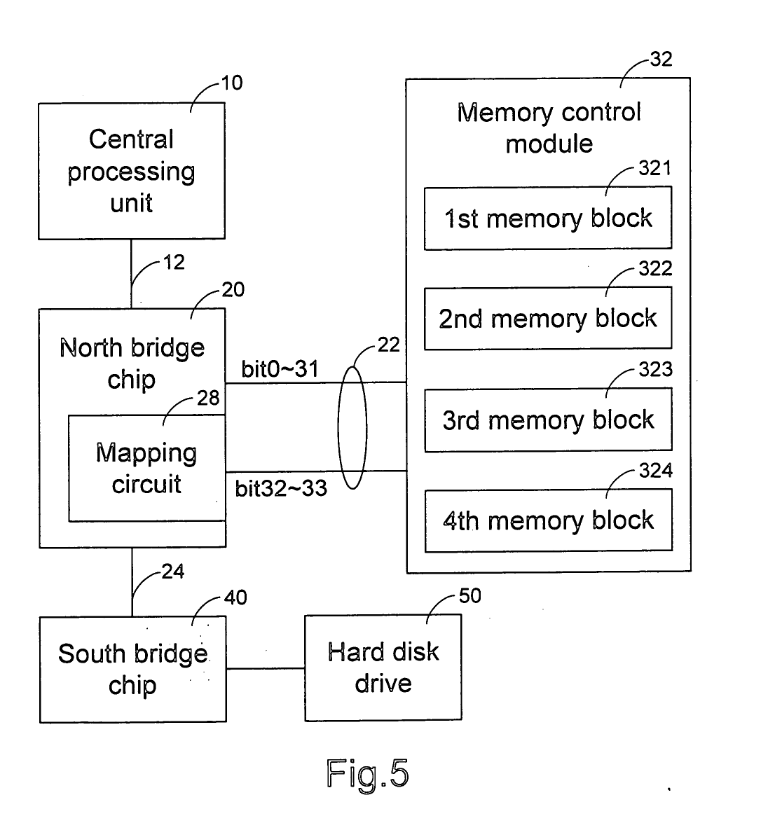

A further embodiment of a memory testing control circuit is illustrated in FIG. 5. In this embodiment, a memory control module having 16-GB address space is to be tested. The memory control module 32 is divided into four memory blocks 321˜324, each of which has address space of 4 GB and addressed via 32 address lines bit0˜bit31. The central processor unit 10, north bridge chip 20, mapping circuit 28, south bridge chip 40 and the hard disc 50 work in a manner similar to the previously described embodiment as shown in FIG. 3, and are not to be redundantly described herein. On the other hand, the control circuit further includes two additional address lines bit32 and bit33 between the mapping circuit 28 of the north bridge chip 20 and the memory control module 30. The mapping circuit 28 changes the logic states of the address lines bit32˜bit33 so as to switch the memory blocks 321˜324 responding to the read/write commands. In this embodiment, the logic state combination of the address lines bit32 and bit33 is one of “00”, “01”, “10” and “11”, which correspond to the memory blocks 321, 322, 323 and 324, respectively.

When the address lines bit32˜bit33 have a combination state “00”, it is the first memory block 321 responding to the central processing unit 10 in response to the data read/write commands. In other words, the address space of the first 4 GB is accessed and tested according to the memory testing tool conventionally specific to the first 4-GB address space. Next, when the memory testing tool stored in the hard disc 50 is executed again by the central processing unit 10 and the state combination of the address lines bit32˜bit33 is “01”, the data read/write commands are mapped onto the second memory block 322 of the memory control module 32 via the mapping circuit 28 so as to test the second memory block 322. Thus, the address space of the second 4 GB is accessed and tested according to the memory testing tool specific to the first memory block 321. Likewise, the memory testing tool stored in the hard disc 50 is executed again to test the third memory block 323 specific to the first memory block 321 when the address lines bit32˜bit33 have a state combination “10”. It can be achieved by mapping the data read/write commands onto the third memory block 323 by the mapping circuit 28. Accordingly, the address space of the third 4 GB is accessed and tested. Afterwards, when the state combination of the address lines bit32˜bit33 is switched into “11”, the data read/write commands asserted in response to the execution of the memory testing tool specific to the first memory block 321 are mapped onto the fourth memory block 324 by the mapping circuit 28 so as to test the fourth memory block 324 of the memory control module 32, i.e. the last 4-GB address space.

In the above embodiments and other modifications, the state switching of the additional address lines, e.g. bit32 and/or bit33, by the mapping circuit 28 can be manually set by the BIOS of the computer system or automatically performed in response to the timing result of a timer (not shown). For example, the output settings of the mapping circuit recorded in the BIOS are manually adjusted whenever the execution of the memory testing tool is completed. Alternatively, the specific time period for executing a single run of memory testing tool is previously calculated so that the mapping circuit 28 periodically switches the logic state of the address lines according to the specific time period and the timing result of the timer.

From the above description, it is understood that the memory testing control circuit and method according to the present invention allow a memory control module having address space greater than 4 GB to be tested in the big real mode.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A control circuit for testing a memory control module, said memory control module comprising first and second memory blocks, said control circuit comprising:
a processing unit executing a memory testing program specific to said first memory block, and asserting data read/write commands; and
a control chip in communication with said processing unit and said memory control module, accessing to said second memory block of said memory control module for test in response to said data read/write commands in a first state.

2. The control circuit according to claim 1 wherein said control chip accesses to said first memory block of said memory control module for test in response to said data read/write commands in a second state.

3. The control circuit according to claim 2 further comprising a mapping circuit for switching said data read/write commands between said first and second states and mapping said data read/write commands in said first state onto said second memory block of said memory control module.

4. The control circuit according to claim 3 wherein said processing unit and said control chip are a central processing unit and a north bridge chip of a computer system, respectively, said mapping circuit is included in said north bridge chip, and said first and second states are different logic states.

5. The control circuit according to claim 2 wherein said control chip changes the level of a specific address line between said control chip and said memory control module to different values so as to switch said read/write commands between said first and second states.

6. The control circuit according to claim 2 wherein said first memory block includes 2ⁿ addresses, said control circuit comprises n counts of address lines corresponding to said read/write commands and at least one specific address line between said control chip and said memory control module for indicating states of said read/write commands.

7. The control circuit according to claim 6 comprising one said specific address line to indicate high-level and low-level states of said read/write commands as said first and second states.

8. The control circuit according to claim 7 wherein said second memory block has the same address space as said first memory block and designated with higher addresses than said first memory block.

9. The control circuit according to claim 8 wherein the value n is equal to 32, and each of said first memory block and said second memory block has a 4-GB address space.

10. The control circuit according to claim 6 comprising m counts of specific address lines, where m is greater than one, to indicate 2^{m} counts of states of said read/write commands for testing third memory blocks of said memory control module in addition to said first and second memory blocks.

11. The control circuit according to claim 10 wherein the value n is equal to 32, and each of said first, second and third memory blocks has a 4-GB address space.

12. The control circuit according to claim 2 further comprising switch-setting means for determining when said first and second states are entered, respectively.

13. The control circuit according to claim 12 wherein said switch-setting means is the BIOS of a computer system or a timer.

14. A control circuit for testing a memory control module of a computer system, said memory control module comprising at least first and second memory blocks, said control circuit comprising:
a central processing unit asserting data read/write commands for testing said
first memory block of said memory control module;
a north bridge chip in communication with said central processing unit and said memory control module, having said first memory block of said memory control module respond to said data read/write commands to be tested at a first time point; and
a mapping circuit in communication with said memory control module, mapping said data read/write commands onto said second memory block of said memory control module to have said second memory block respond to said data read/write commands to be tested at a second time point.

15. The control circuit according to claim 14 wherein said mapping circuit is incorporated into said north bridge chip.

16. The control circuit according to claim 15 further comprising at least one specific address line between said mapping circuit and said memory control module, which have different logic states at said first and second time points.

17. A control method for testing a memory control module, said memory control module having an address space greater than the testing limit of a memory testing tool, said control method comprising steps of:
dividing said memory control module into at least a first memory block and a second memory block, each of said memory blocks having an address space within the testing limit of said memory testing tool;
having said first memory block respond to data read/write commands asserted in response to said memory testing tool in a first situation; and
having said second memory block respond to said data read/write commands in a second situation.

18. The control method according to claim 17 wherein said first and second memory blocks are identical in address space and said second memory block is designed with higher addresses than said first memory block.

19. The control method according to claim 18 wherein said memory testing tool is specific to the test of said first memory block.

20. The control method according to claim 19 further comprising a step of mapping said data read/write commands onto said second memory block in said second situation.

21. The control method according to claim 20 wherein the testing limit of said memory testing tool is 4 GB, and said memory control module is divided into a plurality of memory blocks, each having a 4-GB address space.

22. The control method according to claim 19 wherein said first situation indicates a first logic state of said read/write commands, and said second situation indicates a second logic state of said read/write commands different from said first logic state.

23. The control method according to claim 22 wherein said first and second situations are switched in response to a timing result.

24. The control method according to claim 22 wherein said first and second situations are switched according to the settings in the BIOS.

25. The control method according to claim 22 wherein said memory control module is divided into more than two memory blocks, and more than two different logic states are sequentially imparted to said read/write commands to have said memory blocks respond to said read/write commands in turn.

26. The control method according to claim 22 wherein said first and second logic states of said read/write commands are determined by a mapping circuit incorporated in a north bridge chip and coupled to said memory control module.

27. The control method according to claim 26 wherein said memory testing tool is executed and said read/write commands are asserted by a central processing unit in a big real mode.
